(19) United States
(12) Patent Application Publication
(10) Pub. No.: US 2017/0186944 A1
(43) Pub. Date: Jun. 29, 2017

(54) ENHANCEMENT OF SPIN TRANSFER TORQUE MAGNETORESISTIVE RANDOM ACCESS MEMORY DEVICE USING HYDROGEN PLASMA

(71) Applicants: INTERNATIONAL BUSINESS MACHINES CORPORATION, ARMONK, NY (US); SAMSUNG ELECTRONICS CO., LTD., SUWON-SI (KR)

(72) Inventors: Anthony J. Annunziata, Stamford, CT (US); Gen P. Lauer, Yorktown Heights, NY (US); JungHyuk Lee, Seoul (KR); Jeong-Heon Park, Seoul (KR); Daniel C. Worledge, San Jose, CA (US)

(21) Appl. No.: 14/982,986

(22) Filed: Dec. 29, 2015

(51) Int. Cl. H01L 43/08; H01L 43/02; H01L 43/12

(52) U.S. Cl. CPC H01L 43/08; H01L 43/12; H01L 43/02

(57) ABSTRACT

A method of making a MRAM device includes forming a magnetic tunnel junction on an electrode, the magnetic tunnel junction comprising a reference layer positioned in contact with the electrode, a tunnel barrier layer arranged on the reference layer, and a free layer arranged on the tunnel barrier layer; and depositing an encapsulating layer on and along sidewalls of the magnetic tunnel junction; wherein the exposing of the magnetic tunnel junction to hydrogen plasma is performed at a temperature from about 150 to about 250° C. An MRAM device including an encapsulating layer comprising either silicon nitride or aluminum oxide is also provided.

### BACKGROUND

The present invention relates to spin-transfer torque magnetoresistive random access memory (STT-MRAM devices), and more specifically, to incorporation of hydrogen in stack structures of spin-transfer torque magnetoresistive random access memory devices using hydrogen plasma before encapsulation of the stack.

Spin-transfer torque magnetoresistive random access memory devices have some benefits over semiconductor-based memories, such as dynamic random-access memory (DRAM) and static random-access memory (SRAM). However, in order to compete with dynamic random-access memory and static random-access memory, the spin-transfer torque magnetoresistive random access memory devices are integrated into the wiring layers of standard silicon logic and memory chips.

Spin-transfer torque magnetoresistive random access memory device is a type of solid state, non-volatile memory that uses tunneling magnetoresistance (TMR or MR) to store information. Magnetoresistive random access memory (MRAM) includes an electrically connected array of magnetoresistive memory elements, referred to as magnetic tunnel junctions (MTJs). Each magnetic tunnel junction includes a free layer and fixed/reference layer that each includes a magnetic material layer. A non-magnetic insulating tunnel barrier separates the free and fixed/reference layers. The free layer and the reference layer are magnetically de-coupled by the tunnel barrier. The free layer has a variable magnetization direction, and the reference layer has an invariable magnetization direction.

A magnetic tunnel junction stores information by switching the magnetization state of the free layer. When magnetization direction of the free layer is parallel to the magnetization direction of the reference layer, the magnetic tunnel junction is in a low resistance state. Conversely, when the magnetization direction of the free layer is antiparallel to the magnetization direction of the reference layer, the magnetic tunnel junction is in a high resistance state. The difference in resistance of the MTJ may be used to indicate a logical ‘1’ or ‘0’, thereby storing a bit of information. The tunneling magnetoresistance of a magnetic tunnel junction determines the difference in resistance between the high and low resistance states. A relatively high difference between the high and low resistance states facilitates read operations in the MRAM.

### SUMMARY

According to an embodiment of the invention, a method of making a magnetic random access memory device includes forming a magnetic tunnel junction on an electrode, the magnetic tunnel junction comprising a reference layer positioned in contact with the electrode, a tunnel barrier layer arranged on the reference layer, and a free layer arranged on the tunnel barrier layer; exposing the magnetic tunnel junction to hydrogen plasma; and depositing an encapsulating layer on and along sidewalls of the magnetic tunnel junction.

According to another embodiment of the invention, a method of making a MRAM device includes forming a magnetic tunnel junction on an electrode, the magnetic tunnel junction comprising either a free layer positioned in contact with the electrode, a tunnel barrier layer arranged on the free layer, and a reference layer arranged on the tunnel barrier layer, or a first reference layer positioned in contact with the electrode, a free layer arranged on the first reference layer, and a second reference layer arranged on the free layer; exposing the magnetic tunnel junction to hydrogen plasma; and depositing an encapsulating layer on and along sidewalls of the MTJ.

According to another embodiment of the invention, a MRAM device comprising a magnetic tunnel junction on an electrode, and an encapsulating layer deposited on along sidewalls of the magnetic tunnel junction; the magnetic tunnel junction comprising a reference layer positioned in contact with the electrode, a tunnel barrier layer arranged on the reference layer, and a free layer arranged on the tunnel barrier layer; the encapsulating layer comprising either silicon nitride or aluminum oxide; and wherein the MRAM device has a spin torque switching efficiency improvement of 5-20% compared to a similar device made without hydrogen plasma treatment.

### BRIEF DESCRIPTION OF THE DRAWINGS

The subject matter, which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIGS. 1-3 illustrate exemplary methods of making MRAM devices according to various embodiments, in which:

FIG. 1 is a cross-sectional side view of a patterned magnetic tunnel junction stack positioned on a contact electrode;

FIG. 2 is a cross-sectional side view showing hydrogen plasma treatment of the magnetic tunnel junction stack;

FIG. 3 is a cross-sectional side view after depositing an encapsulating layer on the magnetic tunnel junction stack;

FIG. 4 is a graph illustrating coercive field (Hc) vs critical dimension (CD) for an MRAM device prepared by methods described in various embodiments;

FIG. 5 is a graph illustrating coercive field (Hc) vs critical dimension (CD) for another MRAM device prepared by methods described in various embodiments; and

FIG. 6 is a graph illustrating spin torque switching efficiency for MRAM devices prepared with and without hydrogen plasma treatment.

### DETAILED DESCRIPTION

The major performance metrics of any memory technology include density and power. Reducing the dimensions of MRAM junctions can reduce the programming current needed to switch the cell between two resistance states, which will reduce both the footprint of the unit memory cell and the power. However, smaller MRAM junctions tend to have data retention issues. Data retention in MRAM devices is related to coercive field (Hc) and junction area. As a device gets smaller, Hc tends to decrease as the device becomes smaller and junction area gets smaller as well. A method of maintaining Hc or minimizing Hc loss at smaller device size would allow smaller devices with minimal loss in data retention.

It has been discovered that treatment of a magnetic tunnel junction stack with hydrogen plasma produces a treated magnetic tunnel junction stack with higher coercive field than without the hydrogen plasma treatment. This higher coercive field of magnetic tunnel junction can be incorporated in smaller MRAM devices, for example spin-transfer torque magnetoresistive random access memory devices, to improve data retention.

Another challenge of integrating spin-transfer torque magnetoresistive random access memory devices into the wiring layers of silicon logic and memory chips is encapsulating the spin-transfer torque magnetoresistive random access memory device after patterning. The spin-transfer torque magnetoresistive random access memory device incorporating the hydrogen plasma treated magnetic tunnel junction is encapsulated so that the magnetic layers and tunnel barrier layer experience minimal degradation during subsequent processing. Encapsulation of the hydrogen plasma treated MRAM device can protect the magnetic tunnel junction during subsequent processing and helps to retain the effects of the hydrogen plasma treatment.

Accordingly, various embodiments provide methods of treating magnetic tunnel junction stacks with hydrogen plasma, followed by encapsulating the magnetic tunnel junction stack. The embodiments provide methods of encapsulating devices for perpendicularly magnetized spin-transfer torque magnetoresistive random access memory that use silicon nitride or aluminum oxide. The silicon nitride or aluminum oxide is deposited after the last magnetic tunnel junction etch patterning step and after hydrogen plasma treatment. Encapsulation can be performed by physical vapor deposition (PVD) methods, plasma enhanced chemical vapor deposition (PECVD) methods, Ion-beam deposition (IBD) methods, and the like. The disclosed processes improve device characteristics and reduce magnetic degradation at small device diameters (e.g., <50 nm).

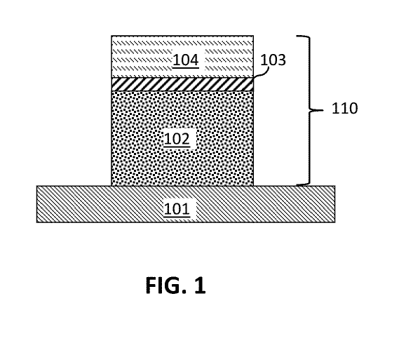

Turning now to the Figures, FIGS. 1-3 illustrate exemplary methods of making MRAM devices according to various embodiments. FIG. 1 is a cross-sectional side view of a patterned magnetic tunnel junction stack 110 positioned on a contact electrode 101. The magnetic tunnel junction stack 110 includes a reference layer 102, a tunnel barrier layer 103, and a free layer 104.

The contact electrode 101 includes a conductive material(s) and forms the bottom contact electrode of the MRAM device. Non-limiting examples of conductive materials for the contact electrode include tantalum, tantalum nitride, titanium, or any combination thereof.

The contact electrode 101 may be formed by depositing a conductive material(s) onto a surface. The conductive material(s) may be deposited by, for example, physical vapor deposition (PVD), ion beam deposition (IBD), atomic layer deposition (ALD), electroplating, or other like processes.

To form the magnetic tunnel junction stack 110, the reference layer 102 is formed on the contact electrode 101; the tunnel barrier layer 103 is formed on the reference layer 102; and the free layer 104 is formed on the tunnel barrier layer 103.

The reference layer 102 and the free layer 104 include conductive, magnetic materials, for example, metals or metal alloys. The reference layer 102 and the free layer 104 may be formed by employing a deposition process, for example, PVD, IBD, ALD, electroplating, or other like processes.

The reference layer 102 and the free layer 104 may include one layer or multiple layers. The reference layer 102 and the free layer 104 may include the same materials and/or layers or different materials and/or layers.

Non-limiting examples of materials for the reference layer 102 and/or the free layer 104 include iron, cobalt, boron, aluminum, nickel, silicon, oxygen, carbon, zinc, beryllium, vanadium, boron, magnesium, or any combination thereof.

The reference layer 102 has a thickness that may generally vary and is not intended to be limited. In some embodiments, the reference layer 102 has a thickness in a range from about 5 to about 25 nm. In other embodiments, the reference layer 102 has a thickness in a range from about 10 to about 15 nm.

The free layer 104 has a thickness that may generally vary and is not intended to be limited. In some embodiments, the free layer 104 has a thickness in a range from about 1 to about 5 nm. In other embodiments, the free layer 104 has a thickness in a range from about 1 to about 2 nm.

The tunnel barrier layer 103 includes a non-magnetic, insulating material. A non-limiting example of an insulating material for the tunnel barrier layer 103 is magnesium oxide (MgO). The tunnel barrier layer 103 may be formed on the reference layer 102 by, for example, radiofrequency (RF) sputtering in some embodiments. Alternatively, the tunnel barrier layer 103 is formed by oxidation (e.g., natural or radical oxidation) of a magnesium (Mg) layer deposited on the reference layer 102. After oxidation, the MgO layer may then be capped with a second layer of Mg. The thickness of the tunnel barrier layer 103 is not intended to be limited and may generally vary.

After depositing the magnetic tunnel junction stack 110 layers on the contact electrode 101, the magnetic tunnel junction stack 110 is patterned. In some embodiments, a hard mask material layer may be disposed on the magnetic tunnel junction stack 110. The hard mask material layer is then patterned by etching, for example, using a reactive ion etch (ME) process or a halogen-based chemical etch process (e.g., including chlorine-containing gas and/or fluorine-containing gas chemistry). The pattern from the hard mask is transferred into the free layer 104, tunnel barrier layer 103, and reference layer 101. The free layer 104, tunnel barrier layer 103, and reference layer 102 are etched by, for example, performing a MRAM stack etch process. The stack etch process may be a ME process or an ion beam etch (IBE) process.

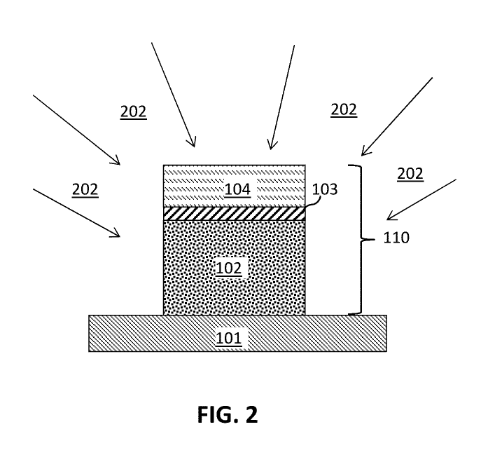

FIG. 2 is a cross-sectional side view of a patterned magnetic tunnel junction stack 110 positioned on a contact electrode 101, and undergoing treatment with hydrogen plasma. The magnetic tunnel junction stack 110 includes a reference layer 102, a tunnel barrier layer 103, and a free layer 104. The arrows 202 shown in the figure are symbolic representations of an environment of hydrogen plasma surrounding the MTJ stack 110 during the hydrogen plasma treatment.

The hydrogen plasma treatment should be performed at a power, temperature, hydrogen pressure, hydrogen flow, and exposure time adequate to allow the hydrogen to sufficiently penetrate the magnetic tunnel junction stack, but not so high as to cause damage to the stack. In some embodiments, the hydrogen plasma treatment is a low power treatment. In some embodiments, exposing the magnetic tunnel junction to hydrogen plasma includes employing a power in a range from about 25 to about 1000 Watts (W), or from about 25 to about 800 W, or from about 25 to about 400 W.

High temperatures could cause damage to the stack, thus it is desired to keep temperatures in a moderate range. In some embodiments, exposing the magnetic tunnel junction to hydrogen plasma occurs at a temperature range from about 100 to about 400° C., or from about 125 to about 300° C., or from about 150 to about 250° C.

In some embodiments, exposing the magnetic tunnel junction to hydrogen plasma occurs at a hydrogen pressure from about 1 to about 8 Torr, or from about 1.3 to about 4 Torr, or from about 1.5 to about 2 Torr. If the tool capability allows, going to even higher pressure might improve hydrogen penetration into the junction and therefore further improve its Hc.

In some embodiments, exposing the MTJ to hydrogen plasma occurs at a hydrogen flow from about 200 to about 1400 standard cubic centimeters per minute (sccm), or from about 600 to about 1200 sccm, or from about 800 to about 1000 sccm.

The hydrogen exposure time depends on pressure, power, flow, and other parameters. In some embodiments, exposing the magnetic tunnel junction to hydrogen plasma occurs over an exposure time of from about 5 to about 200 seconds, or from about 5 to about 100 seconds, or from about 10 to about 20 seconds.

Without being bound by theory, it is believed the exposure to hydrogen plasma allows the penetration of hydrogen at least into the outer portions of the magnetic tunnel junction stack, and that this penetration results in an increase in the coercivity of the free layer of the MRAM device. The mechanism is unknown, but hydrogen may be incorporated in the magnetic tunnel junction structure, or the hydrogen may react with parts of the magnetic tunnel junction, such as oxygen atoms.

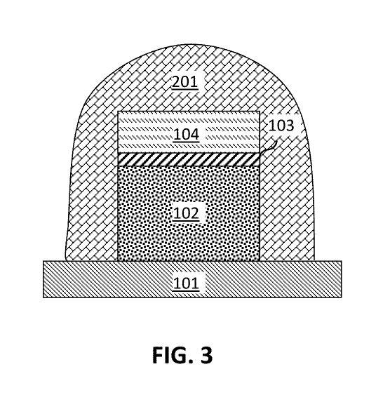

FIG. 3 is a cross-sectional side view after depositing an encapsulating layer 201 on the magnetic tunnel junction stack 110, the encapsulation occurring after hydrogen plasma treatment. The encapsulating layer 201 includes one or more insulating materials. The insulating layer 201 encapsulates the magnetic tunnel junction stack 110. The encapsulating layer 201 is deposited on the exposed surface and sidewalls of the magnetic tunnel junction stack 110 and contacts the contact electrode 101.

The thickness of the encapsulating layer 201 may generally vary and is not intended to be limited. In some embodiments, the thickness of the encapsulating layer 201 is in a range from about 10 to about 60 nm. In other embodiments, the thickness of the encapsulating layer 201 is in a range from about 25 to about 40 nm. To achieve a desired encapsulating layer thickness of, for example, silicon nitride, several cycles of deposition may be performed. To achieve a desired encapsulating layer thickness of, for example, aluminum oxide, several cycles of deposition and oxidation may be performed.

The encapsulating layer 201 may be deposited by deposition methods such as plasma enhanced chemical vapor deposition (PECVD), physical vapor deposition (PVD), ion-beam deposition (IBD), and the like, or a combination of these deposition methods.

In some embodiments, the encapsulating layer 201 can be deposited using a PECVD method. The PECVD method may be performed at a temperature range from about 60 to about 400° C., or from about 200 to about 300° C.

In some embodiments, the encapsulating layer 201 can be deposited using a PVD method. The deposition conditions for forming the encapsulating layer 201 using PVD methods includes low sample temperatures (e.g., about room temperature), low power and deposition rates, and slightly reactive plasma. The PVD method may be performed at a temperature range from about 20 to about 25° C., or at room temperature.

The encapsulating layer 201 may include, for example, AlOx or SiNx. Sub-stoichiometric amounts of AlOx and SiNx may be formed using various levels of the appropriate reactive gas (O₂ or N₂). The encapsulating film 201 may include, for example, SiNₓ or AlOₓ, wherein x is the ratio of N to Si and O to Al, respectively, and x may be varied to range from pure elemental Si/Al to stoichiometric Si₃N₄ or Al₂O₃. In one embodiment, the encapsulating layer 201 includes SiNₓ, and x is from 0 to 1.33 (i.e., pure Si to Si₃N₄). In another embodiment, the encapsulating layer 201 includes AlOₓ, and x is from 0 to 1.5 (i.e., pure Al to Al₂O₃).

In some embodiments, the magnetic tunnel junction comprises a free layer positioned in contact with the electrode, a tunnel barrier layer arranged on the free layer, and a reference layer arranged on the tunnel barrier layer.

In other embodiments, the magnetic tunnel junction comprises a first reference layer positioned in contact with the electrode, a free layer arranged on the first reference layer, and a second reference layer arranged on the free layer. The first and second reference layers are formed in a similar manner to the reference layers of the preceding embodiments. In some embodiments the first and second reference layers are the same, in other embodiments they can be different (for example they may be different in terms of composition, thickness, deposition method, and the like).

As described above, various embodiments provide methods of hydrogen plasma treatment of devices for perpendicularly magnetized spin-transfer torque magnetoresistive random access memory, followed by encapsulation that uses deposited silicon nitride or aluminum oxide to encapsulate the MRAM device. The silicon nitride or aluminum oxide is deposited after the last magnetic tunnel junction etch patterning step. Preferably the encapsulation step immediately follows the hydrogen plasma treatment. In some embodiments there can be a vacuum break between hydrogen plasma treatment and encapsulation. It is preferable to avoid a vacuum break to avoid exposure of the device to air.

In some embodiments the MRAM device made according to the methods above has a coercive field that is higher by at least 5%, 10%, 20%, or 30% or more than the coercive field of a similar device made without hydrogen treatment.

In some embodiments the MRAM device made according to the methods above has a spin torque switching efficiency that is higher by 5-20% than the spin torque switching efficiency of a similar device made without hydrogen plasma treatment.

In some embodiments the MRAM device of the invention may undergo further processing. The further processing can include depositing an interlayer dielectric (ILD) layer on the magnetic tunnel junction stack 110. The ILD layer may include, for example, a low-k dielectric oxide, including but not limited to, silicon dioxide, spin-on-glass, a flowable oxide, a high-density plasma oxide, or any combination thereof. The ILD layer may be formed by performing deposition process, including, but not limited to spin coating, CVD, PVD, plasma enhanced CVD, chemical solution deposition, or like processes. The further processing can also include embedding the encapsulated device into the back-end-of-line (BEOL) of a CMOS process route. The encapsulated device may undergo additional processing after the BEOL of the CMOS route.

### EXAMPLES

### Example 1

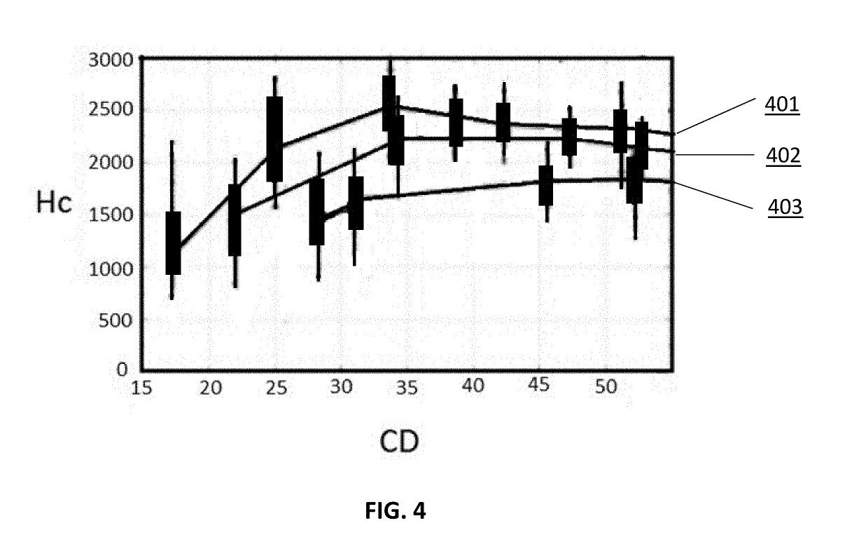

FIG. 4 is a graph illustrating an MRAM device degradation using PVD encapsulating layer formation methods described herein. The graph shows coercivity (H_{c}) (Oₑ) as a function of CD (nm) (critical dimension (CD) measured by transmission electron microscopy (TEM)).

Trace 401 shows coercivity of a device that was made using the hydrogen plasma treatment as described herein, followed by encapsulation with a silicon nitride layer that was deposited using PVD methods. For comparison, trace 402 shows coercivity of a device that was made using the hydrogen plasma treatment as described herein, followed by encapsulation with a silicon nitride layer that was deposited using PECVD methods as described herein, and trace 403 shows coercivity of a device made without exposure to hydrogen plasma. The traces show that coercivity is higher for devices made with the hydrogen plasma treatment method. For those devices made with the hydrogen plasma treatment method, devices encapsulated with a silicon nitride layer deposited using PECVD methods show higher coercivity than devices encapsulated with a silicon nitride layer deposited using PVD methods.

### Example 2

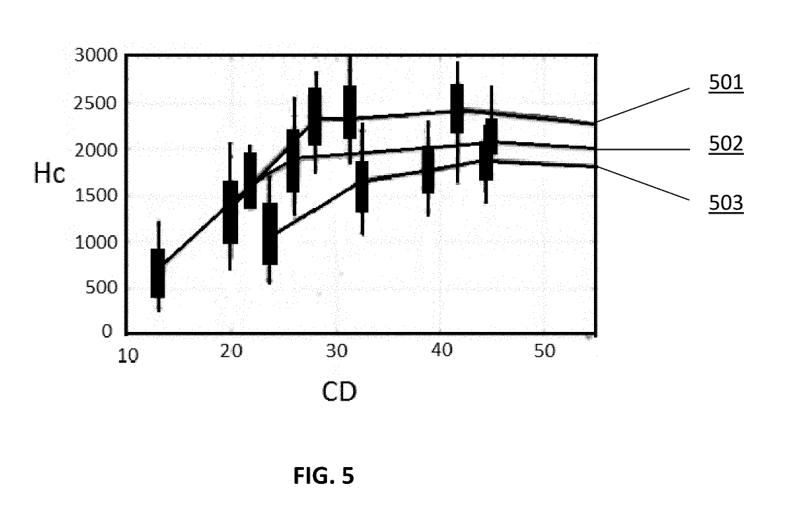

FIG. 5 is a graph illustrating coercivity (H_{c}) vs critical dimension (CD) for additional MRAM devices prepared by methods described in various embodiments. The graph shows coercivity (H_{c}) (Oe) as a function of CD (nm) (critical dimension (CD) measured by transmission electron microscopy (TEM)).

Trace 501 shows coercivity of a device that was made using the hydrogen plasma treatment as described herein, followed by encapsulation with a silicon nitride layer that was made using PVD methods. For comparison, trace 502 shows coercivity of a device that was made using the hydrogen plasma treatment as described herein, followed by encapsulation with a silicon nitride layer that was made using PECVD methods as described herein, and trace 503 shows coercivity of a device made without exposure to hydrogen plasma. The traces show that coercivity is higher for devices made with the hydrogen plasma treatment method. For those devices made with the hydrogen plasma treatment method, devices encapsulated with a silicon nitride layer deposited using PECVD methods show higher coercivity than devices encapsulated with a silicon nitride layer deposited using PVD methods.

### Example 3

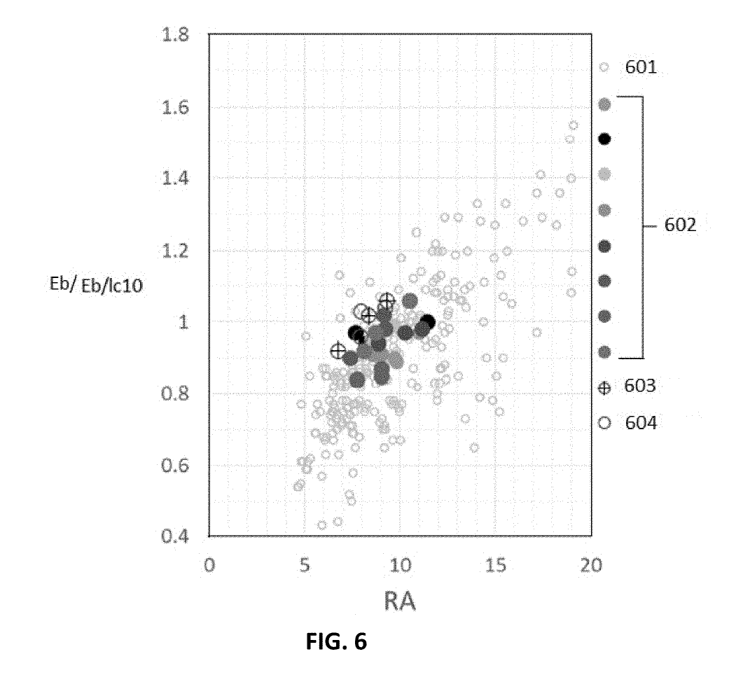

FIG. 6 is a graph illustrating spin torque switching efficiency (Eb/lc10) as a function of Resistance-Area (RA) for MRAM devices prepared with and without hydrogen plasma treatment. RA is calculated by multiplying Rₘᵢₙ and Area of the junction. There are two resistance states of each junction, a lower resistance state and a higher resistance state. Rₘᵢₙ is the lower resistance state. The unit of RA is (ohm*μm²).

Small open circles 601 depict data points for devices made by standard procedures, including no hydrogen plasma treatment. Filled circles 602 depict data for devices made with no hydrogen plasma treatment, but may have been exposed to other plasma treatments such as with ammonia, helium, or nitrogen. Large circles with crosses 603 depict data for devices made using the hydrogen plasma treatment as described herein, followed by encapsulation with a silicon nitride layer that was made using PVD methods. Large open circles 604 depict data for devices made using the hydrogen plasma treatment as described herein, followed by encapsulation with a silicon nitride layer that was made using PECVD methods. The data show that for a given RA, devices made using the hydrogen plasma treatment as described herein have higher spin torque switching efficiency than devices made without the hydrogen plasma treatment.

### Example 4

Table 1 below illustrates H_{c} (Oe) for CD sizes of 10 nm and 35 nm for MRAM devices prepared with and without hydrogen plasma treatment. The data show the benefit of the hydrogen plasma treatment for increasing the H_{c} values at both the 10 nm and 35 nm CD sizes. The process wherein hydrogen plasma treatment is followed by encapsulation by a PVD method is particularly advantageous.

TABLE 1
H_{c} (Oe) for CD sizes of 10 nm and 35 nm

| Process | H_{c}@10 nm CD | H_{c}@ 35 nm CD |
|---|---|---|
| PECVD/no hydrogen | 1343.8 | 1692 |
| PVD/hydrogen plasma | 1718.8 | 2506 |
| PECVD/hydrogen plasma | 1593.8 | 2219 |

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of making a magnetic random access memory (MRAM) device, the method comprising:
forming a magnetic tunnel junction on an electrode, the magnetic tunnel junction comprising a reference layer positioned in contact with the electrode, a tunnel barrier layer arranged on the reference layer, and a free layer arranged on the tunnel barrier layer;
exposing the magnetic tunnel junction to hydrogen plasma; and
depositing an encapsulating layer on and along sidewalls of the magnetic tunnel junction.

2. The method of claim 1, wherein exposing the magnetic tunnel junction to hydrogen plasma includes employing a power in a range from about 25 to about 1000 Watts (W), or from about 25 to about 400 W.

3. The method of claim 1, wherein exposing the magnetic tunnel junction to hydrogen plasma occurs at a temperature range from about 100 to about 400° C., or from about 125 to about 300° C., or from about 150 to about 250° C.

4. The method of claim 1, wherein exposing the magnetic tunnel junction to hydrogen plasma occurs at a hydrogen pressure from about 1 to about 8 Torr, or from about 1.3 to about 4 Torr, or from about 1.5 to about 2 Torr.

5. The method of claim 1, wherein exposing the magnetic tunnel junction to hydrogen plasma occurs at a hydrogen flow from about 200 to about 1400 standard cubic centimeters per minute (sccm), or from about 600 to about 1200 sccm, or from about 800 to about 1000 sccm.

6. The method of claim 1, wherein exposing the magnetic tunnel junction to hydrogen plasma occurs over an exposure time of from about 5 to about 200 seconds, or from about 5 to about 100 seconds, or from about 10 to about 20 seconds.

7. The method of claim 1, wherein the depositing the encapsulating layer comprises depositing by ion-beam deposition.

8. The method of claim 1, wherein depositing the encapsulating layer comprises depositing by plasma enhanced chemical vapor deposition.

9. The method of claim 8, wherein the chemical vapor deposition is performed at a temperature range from about 100 to about 250° C., or from about 150 to about 200° C.

10. The method of claim 1, wherein depositing the encapsulating layer comprises depositing by physical vapor deposition.

11. The method of claim 1, wherein the encapsulating layer is deposited by a combination of one or more of ion beam deposition, plasma-enhanced chemical vapor deposition, or physical vapor deposition.

12. The method of claim 10, wherein the physical vapor deposition is performed at a temperature range from about 20 to about 25° C., or at room temperature.

13. The method of claim 1, wherein the encapsulating layer comprises silicon nitride, aluminum oxide, or a combination thereof.

14. The method of claim 1, wherein the encapsulating layer comprises silicon nitride.

15. The method of claim 1, wherein the MRAM device is a spin torque transfer MRAM (STT-MRAM) device.

16. A method of making a magnetic random access memory device, the method comprising:
forming a magnetic tunnel junction on an electrode, the magnetic tunnel junction comprising either a free layer positioned in contact with the electrode, a tunnel barrier layer arranged on the free layer, and a reference layer arranged on the tunnel barrier layer, or a first reference layer positioned in contact with the electrode, a free layer arranged on the first reference layer, and a second reference layer arranged on the free layer; and
exposing the magnetic tunnel junction to hydrogen plasma; and
depositing an encapsulating layer on and along sidewalls of the magnetic tunnel junction.

17. The method of claim 16, wherein the encapsulating layer comprises silicon nitride and is deposited by a PVD process.

18. The method of claim 16, wherein the exposing of the magnetic tunnel junction to hydrogen plasma is performed with a power from about 25 Watts to about 400 Watts, at a temperature from about 150 to about 250° C., at a hydrogen pressure from about 1.5 to about 2 Torr, with a hydrogen flow from about 800 to about 1000 standard cubic centimeters per minute, for an exposure time from about 10 to about 20 seconds

19. An MRAM device comprising a magnetic tunnel junction on an electrode, and an encapsulating layer deposited on along sidewalls of the magnetic tunnel junction;
the magnetic tunnel junction comprising a reference layer positioned in contact with the electrode, a tunnel barrier layer arranged on the reference layer, and a free layer arranged on the tunnel barrier layer;
the encapsulating layer comprising either silicon nitride or aluminum oxide; and
wherein the MRAM device has a spin torque switching efficiency improvement of 5-20% compared to a similar device made without hydrogen plasma treatment.

20. The MRAM device according to claim 19, wherein the encapsulating layer comprises silicon nitride and is deposited by a PVD process.
